(19) United States
(12) Patent Application Publication
(10) Pub. No.: US 2015/0056381 A1
(43) Pub. Date: Feb. 26, 2015

(54) METHOD FOR FORMING CONDUCTIVE FILM

(71) Applicants: NATIONAL UNIVERSITY CORPORATION NAGOYA UNIVERSITY, Nagoya-shi, Aichi (JP); TOKYO ELECTRON LIMITED, Tokyo (JP)

(72) Inventors: Masaru Hori, Nagoya-shi (JP); Hirotaka Toyoda, Nagoya-shi (JP); Makoto Sekine, Nagoya-shi (JP); Keigo Takeda, Nagoya-shi (JP); Hiroki Kondo, Nagoya-shi (JP); Kenji Ishikawa, Nagoya-shi (JP); Yusuke Kubota, Tsukuba-shi (JP); Hitoshi Itoh, Nagoya-shi (JP); Hidenori Miyoshi, Nirasaki-shi (JP)

(21) Appl. No.: 14/381,100

(22) PCT Filed: Feb. 14, 2013
(86) PCT No.: PCT/JP2013/053473

§ 371 Date: Aug. 26, 2014

(30) Foreign Application Priority Data
Feb. 28, 2012 (JP) 2012-041556

(51) Int. Cl. H01B 13/00; C23C 26/00; H01J 37/32; C23C 24/00

(52) U.S. Cl. CPC H01B 13/0026; C23C 24/00; C23C 26/00; H01J 37/32229; H01J 37/3222; H01J 37/32266; H01J 37/32522; H01B 13/003; H01J 2237/327; H01J 2237/336
USPC 427/535

(57) ABSTRACT

A method for forming a conductive film on a substrate includes forming a precursor-containing film on the substrate; and irradiating plasma of a treatment gas to the precursor-containing film by an atmospheric pressure plasma treatment device, removing the organic substances and forming a conductive film from the metallic fine particles or the metallic compounds, the atmospheric pressure plasma treatment device including: a microwave generator, a hollow waveguide, a gas supply device, and an antenna portion configured to discharge to the outside, whereby the treatment gas being converted to plasma by the microwaves, the plasma thus generated being irradiated to the precursor-containing film on the substrate, and a hydrogen radical density of the plasma at a position spaced apart 7 mm from the slot holes being equal to or higher than 2×10¹⁴/cm³.

### TECHNICAL FIELD

The present disclosure relates to a method for forming a conductive film from metallic fine particles or metallic compounds using plasma.

### BACKGROUND

For a technique of forming a fine conductive film, a method of using a paste or an ink which contains metallic fine particles or metallic compounds is known. For example, Patent Document 1 (the publication gazette of Japanese Patent No. 4285197) proposes a method that forms a circuit by supplying a paste, which contains metal nano particles, onto a surface of a substrate and then performing an oxygen plasma treatment to remove organic substances and to flocculate the metal nano particles. Furthermore, Patent Document 2 (the publication gazette of Japanese Patent Application Publication No. 2011-77268) suggests a method that forms a conductive film by coating a conductive ink, which is obtained by mixing metal nano particles and a dispersant with a solvent, onto a substrate, irradiating oxygen plasma on the conductive ink, and then performing the irradiation of hydrogen plasma on the conductive ink.

For the techniques of Patent Documents 1 and 2, the treatment using oxygen plasma is essential. The oxygen plasma has an advantage in that the efficiency of decomposing organic substances contained in the paste or the ink is high. However, the oxygen plasma shows strong oxidizing power. Thus, there is a concern that a resultant metal film may be oxidized and a specific resistance thereof may be increased. For that reason, in Patent Document 2, a reduction treatment using hydrogen plasma is combined after the oxygen plasma treatment. This leads to an increase in the number of steps. In Comparative Example 1 of Patent Document 2, there is disclosed an instance in which the removal of organic substances becomes insufficient when performing only the hydrogen plasma treatment.

As mentioned above, in the related art, one problem is that performing only the oxygen plasma treatment leads an oxide film to be formed on the conductive film, thereby increasing its specific resistance. If this problem is solved by additionally performing a hydrogen plasma treatment, another problem is that the number of steps increases. Moreover, if only the hydrogen plasma treatment is performed in order not to increase the number of steps, the removal of organic substances becomes insufficient. This poses a problem in that it becomes difficult to form a high-quality conductive film.

### SUMMARY

The present disclosure provides a method capable of forming a high-quality conductive film from metallic fine particles or metallic compounds in a simple manner and within a short period of time.

A method of forming a conductive film according to the present disclosure relates to a method for forming a conductive film on a substrate. The method of forming the conductive film according to the present disclosure includes: a step of forming a precursor-containing film, which contains metallic fine particles or metallic compounds and organic substances, on the substrate; and a step of irradiating plasma of a treatment gas including a hydrogen gas to the precursor-containing film by an atmospheric pressure plasma treatment device, removing the organic substances and forming a conductive film from the metallic fine particles or the metallic compounds.

In the method of forming the conductive film according to the present disclosure, the atmospheric pressure plasma treatment device includes: a microwave generator configured to generate microwaves; a hollow waveguide connected to the microwave generator and elongated in a transmission direction of the microwaves; the waveguide having a rectangular cross section in a direction orthogonal to the transmission direction; a gas supply device connected to the waveguide and configured to supply the treatment gas into the waveguide; and an antenna portion which constitutes a portion of the waveguide and has one or more rectangular slot holes, the antenna portion configured to discharge plasma generated by the microwaves to the outside. In the atmospheric pressure plasma treatment device, the one or more rectangular slot holes being formed at a short-side-constituting wall of a cross section of the antenna portion such that the transmission direction of the microwaves coincides with a longitudinal direction of the slot holes.

Further, in the step of irradiating plasma, the treatment gas supplied into the waveguide kept in an atmospheric pressure state being converted to plasma at the slot holes by the microwaves, the plasma thus generated being irradiated from the slot holes to the precursor-containing film on the substrate, and a hydrogen radical density of the plasma at a position spaced apart 7 mm from the slot holes being equal to or higher than 2×10¹⁴/cm³.

In the method of forming the conductive film according to the present disclosure, the irradiation of the plasma may be performed by setting an interval between the slot holes and the precursor-containing film to fall within a range of from 1 mm to 12 mm.

In the method of forming the conductive film according to the present disclosure, at the step of irradiating the plasma, the plasma may be generated by using a mixed gas of a hydrogen gas and an argon gas as the treatment gas and setting a total flow rate of the treatment gas including the hydrogen gas at a percentage of 0.5 percent by volume to 4 percent by volume to fall within a range of from 10 slm (a standard state L/min) to 50 slm (a standard state L/min).

In the method of forming the conductive film according to the present disclosure, the plasma treatment device further includes a pulse generator and generates the plasma by generating the microwaves in a pulse-like form at a duty ratio of 5% or more.

In the method of forming the conductive film according to the present disclosure, prior to irradiating the plasma, the precursor-containing film may be heated to a temperature of from room temperature to 300 degrees C. and the plasma is irradiated while maintaining the temperature.

In the method of forming the conductive film according to the present disclosure, by treating metallic fine particles or metallic compounds with the plasma having a high hydrogen radical density, it is possible to form a high-quality conductive film from the metallic fine particles or the metallic compounds within a short period of time.

### BRIEF DESCRIPTION OF THE DRAWINGS

FIG. 1 is a schematic configuration diagram of a plasma treatment device according to one embodiment of the present disclosure.

FIG. 2 is a view illustrating a configuration example of a microwave generator.

FIG. 3 is a view illustrating a configuration example of a control unit.

FIG. 4 is a perspective view used in describing slot holes of an antenna portion of a waveguide.

FIG. 5 is a plan view of a formation surface of the slot holes shown in FIG. 4.

FIG. 6 is a perspective view used in describing another arrangement example of slot holes of an antenna portion of a waveguide.

FIG. 7 is a plan view of a formation surface of the slot holes shown in FIG. 6.

FIG. 8 is a view illustrating one example of a cross-sectional shape of slot holes.

FIG. 9 is a graph illustrating the relationship between a distance from the slot holes for atmospheric pressure plasma and a hydrogen radical density in the plasma.

FIG. 10 is a graph illustrating the relationship between the total flow rate of a treatment gas for the atmospheric pressure plasma and the hydrogen radical density in the plasma.

FIG. 11 is a graph illustrating the relationship between a H₂ gas concentration in the treatment gas for the atmospheric pressure plasma and the hydrogen radical density in the plasma.

FIG. 12 is a graph illustrating the relationship between a duty ratio of microwave pulses for the atmospheric pressure plasma and the hydrogen radical density in the plasma.

FIGS. 13A and 13B are SEM (Scanning Electron Microscope) images of a coated film containing silver nano particles prior to performing an atmospheric pressure plasma treatment in Example 1, FIG. 13A being an image of the surface of the coated film taken at a magnification of 10,000 and FIG. 13B being an image of the cross section of the coated film taken at a magnification of 100,000.

FIGS. 14A and 14B are SEM (Scanning Electron Microscope) images of a conductive film after performing the atmospheric pressure plasma treatment in Example 1, FIG. 14A being an image of the surface of the conductive film taken at a magnification of 10,000 and FIG. 14B being an image of the cross section of the conductive film taken at a magnification of 100,000.

FIGS. 15A and 15B are SEM (Scanning Electron Microscope) images of a conductive film after performing the atmospheric pressure plasma treatment in Example 2, FIG. 15A being an image of the surface of the conductive film taken at a magnification of 10,000, FIG. 15B being an image of the surface of the conductive film taken at a magnification of 100,000.

### DETAILED DESCRIPTION

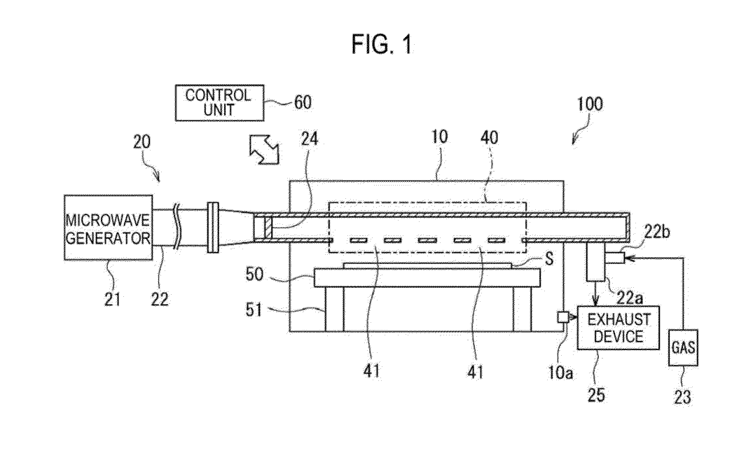

Embodiments of the present disclosure will now be described in detail with reference to the accompanying drawings. Referring to FIGS. 1 to 8, a configuration of a plasma treatment device which can be used in a method for forming a conductive film according to the present embodiment will be described.

FIG. 1 is a sectional view showing a schematic configuration of a plasma treatment device 100 that can be used in the present embodiment. The plasma treatment device 100 shown in FIG. 1 includes a treatment vessel 10, a plasma generator 20 that generates plasma and irradiates the plasma toward a substrate S located within the treatment vessel 10, a stage 50 that supports the substrate S and a control unit 60 that controls the plasma treatment device 100. The plasma treatment device 100 is configured as an atmospheric pressure plasma treatment device that performs a treatment with respect to the substrate S under normal pressure.

### <Treatment Vessel>

The treatment vessel 10 is a vessel for defining a plasma treatment space and can be made of a metal such as, e.g., aluminum or stainless steel. It is preferred that the interior of the treatment vessel 10 is subjected to a surface treatment for increasing plasma erosion resistance such as, e.g., an alumite treatment or the like. In the treatment vessel 10, an opening is formed through which the substrate S is carried in and out (not shown). In the plasma treatment device 100 as an atmospheric pressure plasma treatment device, the treatment vessel 10 is not essential but is an optional configuration.

### <Plasma Generator>

The plasma generator 20 includes a microwave generator 21 that generates microwaves, a rectangular waveguide 22 which is connected to the microwave generator 21, a gas supply device 23 which is connected to the rectangular waveguide 22 to supply a treatment gas into the rectangular waveguide 22, and an exhaust device 25 configured to exhaust a gas within an antenna portion 40 and, if necessary, evacuate the interior of the treatment vessel 10. In the plasma generator 20, a partition wall 24 made of a dielectric material such as quartz or the like is arranged within the rectangular waveguide 22 in order to block the passage of the treatment gas. In addition, the plasma generator 20 includes an antenna portion 40 which has one or more slot holes 41 formed on one wall surface of the rectangular waveguide 22 and discharges the generated plasma toward the external substrate S through the slot holes 41.

### (Microwave Generator)

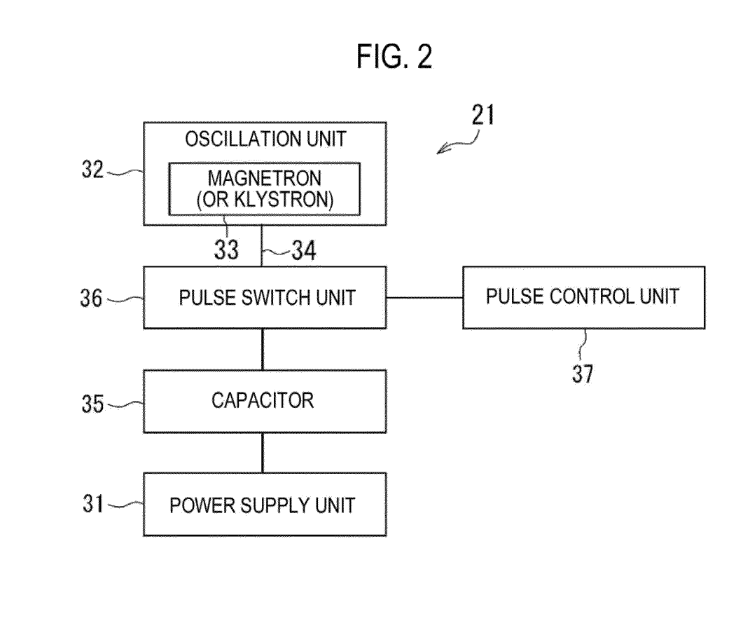

The microwave generator 21 generates microwaves having a frequency within a range of, e.g., 2.45 GHz to 100 GHz, or 2.45 GHz to 10 GHz. The microwave generator 21 has a pulse generating function and can generate pulse-like microwaves. One configuration example of the microwave generator 21 is shown in FIG. 2. In the microwave generator 21, a capacitor 35 and a pulse switch unit 36 are installed at a high-voltage line 34 extending from a power supply unit 31 to a magnetron (or a klystron) 33 of an oscillation unit 32. In addition, a pulse control unit 37 is connected to the pulse switch unit 36. The pulse control unit 37 performs the input of a control signal configured to control a frequency, a duty ratio or the like. The pulse control unit 37 receives an instruction from a controller 61 (to be described later) of the control unit 60 and outputs a control signal toward the pulse switch unit 36. By inputting the control signal to the pulse switch unit 36 while supplying a high voltage from the power supply unit 31, rectangular waves having a predetermined voltage are supplied to the magnetron (or the klystron) 33 of the oscillation unit 32. Thus, pulse-like microwaves are outputted. Since heat is easily accumulated in the antenna portion 40 when a discharge of the antenna portion 40 is continuously performed, the pulse generation function is set for the purpose of preventing transition from a low-temperature non-equilibrium discharge to an arc discharge. If a mechanism for cooling the antenna portion 40 is additionally installed, the pulse generation function is not essential but is an optional configuration.

While not shown in the drawings, the microwaves generated from the microwave generator 21 are transmitted to the antenna portion 40 of the rectangular waveguide 22 through an isolator configured to control a moving direction of the microwaves or a matcher configured to match the impedance of the waveguide.

### (Waveguide)

The rectangular waveguide 22 is elongated in a transmitting direction of the microwaves. In addition, the cross section of the rectangular waveguide 22 in a direction orthogonal to the transmitting direction of the microwaves is rectangular. The rectangular waveguide 22 is made of a metal such as, e.g., copper, aluminum, iron or stainless steel, or an alloy thereof.

The rectangular waveguide 22 includes the antenna portion 40 as a part thereof. The antenna portion 40 has one or more slot holes 41 formed at, e.g., a wall which constitutes a short side of the cross section of the antenna portion 40. That is to say, the antenna portion 40 is a portion of the rectangular waveguide 22, in which the slot holes 41 are formed. In FIG. 1, the antenna portion 40 is surrounded by a single-dot chain line. The length of the antenna portion 40 may be decided according to the size of the substrate S. The length of the antenna portion 40 may be set to fall within a range of, e.g., 0.3 m to 1.5 m. The slot holes 41 are openings extending through, e.g., a wall which constitutes the short side of the cross section of the antenna portion 40. The slot holes 41 are formed opposite the substrate S in order to irradiate plasma toward the substrate S. In addition, the arrangement and shape of the slot holes 41 will be described later.

The plasma generator 20 further includes a partition wall 24 which is arranged within the rectangular waveguide 22 between the microwave generator 21 and the antenna portion 40 in order to block the passage of the treatment gas. The partition wall 24 is made of a dielectric material such as, e.g., quartz or Teflon (registered trademark: polytetrafluoroethylene). The partition wall 24 allows the passage of microwaves but prevents the treatment gas within the rectangular waveguide 22 from flowing toward the microwave generator 21.

### (Gas Supply Device)

The gas supply device (GAS) 23 is connected to a gas introduction portion 22b installed in a branch pipe 22a branched from the rectangular waveguide 22. The gas supply device 23 includes gas supply sources, valves and flow rate controllers, all of which are not shown in the drawings. The gas supply sources are provided according to the kind of treatment gases used. Examples of the treatment gases include a hydrogen gas, a nitrogen gas, an oxygen gas, a water vapor and a Freon (CF₄) gas. In case of the Freon (CF₄) gas, the exhaust device 25 needs to be used. Moreover, it may be possible to install a supply source for an inert gas such as, e.g., an argon gas, a helium gas or a nitrogen gas. The treatment gases supplied from the gas supply device 23 into the rectangular waveguide 22 are converted to plasma because a discharge occurs in the slot holes 41 by the microwaves. When forming a conductive film, a hydrogen gas and an inert gas can be used as the treatment gases.

### (Exhaust Device)

The exhaust device 25 includes a valve, a turbo molecular pump and a dry pump, etc., all of which are not shown in the drawings. In order to evacuate the interior of the rectangular waveguide 22 and the interior of the treatment vessel 10, the exhaust device 25 is connected to the branch pipe 22a of the rectangular waveguide 22 and the exhaust port 10a of the treatment vessel 10. For example, the treatment gas remaining within the rectangular waveguide 22 at the time of process stoppage can be rapidly removed by operating the exhaust device 25. At the time of startup of a discharge, the exhaust device 25 is used to efficiently replace the atmospheric gas existing within the rectangular waveguide 22 and the treatment vessel 10 with the treatment gas. In the plasma treatment device 100 as the atmospheric pressure plasma treatment device, the exhaust device 25 is not essential but is an optional configuration. However, if, just like a CF₄ gas, the treatment gas is stable at a normal temperature but, when converted to plasma, may possibly generate highly reactive fluorine radicals F or fluorocarbon radicals CₓF_{y}, etc., it is desirable to install the exhaust device 25.

### <Stage>

The stage 50 horizontally supports the substrate S within the treatment vessel 10. The stage 50 is installed in such a state that it is supported by a support portion 51 installed at the bottom portion of the treatment vessel 10. Examples of a material of which the stage 50 and the support portion 51 are made include quartz, a ceramic material such as AlN, Al₂O₃, BN or the like, and a metallic material such as Al, stainless steel or the like. If necessary, a heater may be embedded in the stage 50 so as to heat the substrate S to 280 degrees C. or so. In the plasma treatment device 100, the stage 50 may be installed depending on the kind of the substrate S, and the stage 50 is an optional configuration.

### <Substrate>

The plasma treatment device 100 may use, as the substrate S, e.g., a FPD (Flat Panel Display) substrate represented by a glass substrate for an LCD (Liquid Crystal Display) or a film member such as a polycrystalline silicon film, a polyimide film or the like. Particularly, for a simple configuration, in the plasma treatment device 100 it is possible to generate plasma having a linear shape, by forming the antenna portion 40 into an elongated shape with a length of about one meter. For that reason, in the plasma treatment device 100, it is possible to efficiently perform a uniform plasma treatment with respect to a substrate S having an increased width and a relatively large area, such as, e.g., a substrate/film for a FPD (Flat Panel Display), a solar cell or an organic EL element.

### <Control Unit>

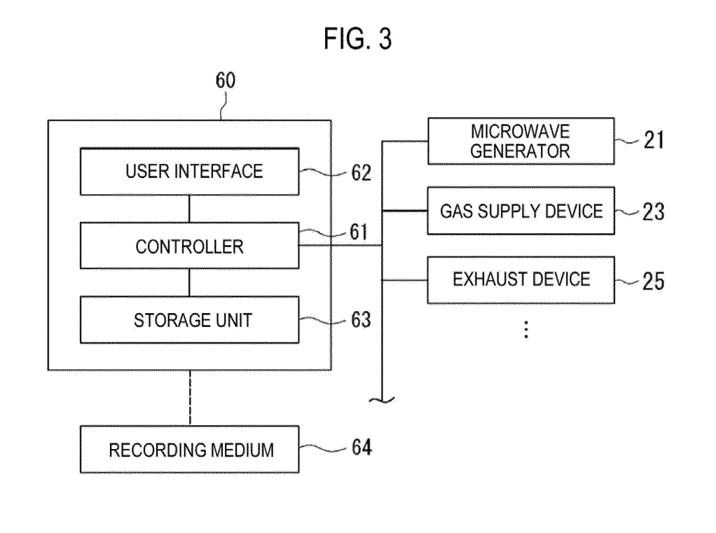

The respective constituent parts that constitute the plasma treatment device 100 are connected to, and controlled by, the control unit 60. As illustrated in FIG. 3, the control unit 60 having a computer function includes a controller 61 provided with a CPU, a user interface 62 connected to the controller 61 and a storage unit 63. The storage unit 63 stores control programs (software) for realizing, under the control of the controller 61, different kinds of treatments to be performed in the plasma treatment device 100 and recipes in which treatment condition data and the like are recorded. Depending on the necessity, an arbitrary control program or an arbitrary recipe is called out from the storage unit 63 pursuant to an instruction or the like sent from the user interface 62 and then executed by the controller 61. Thus, a desired treatment is performed in the plasma treatment device 100 under the control of the control unit 60. The control programs or the recipes on the treatment condition data or the like can be used by installing the control programs or the recipes stored in a computer-readable recording medium 64 into the storage unit 63. While there is no particular limitation, it is possible to use, as the computer-readable recording medium 64, e.g., a CD-ROM, a hard disc, a flexible disc, a flash memory, a DVD or the like. In addition, the recipes can also be used on an online basis by transmitting the recipes from other devices through, e.g., a dedicated line, whenever needed.

### <Configuration of Slot Holes>

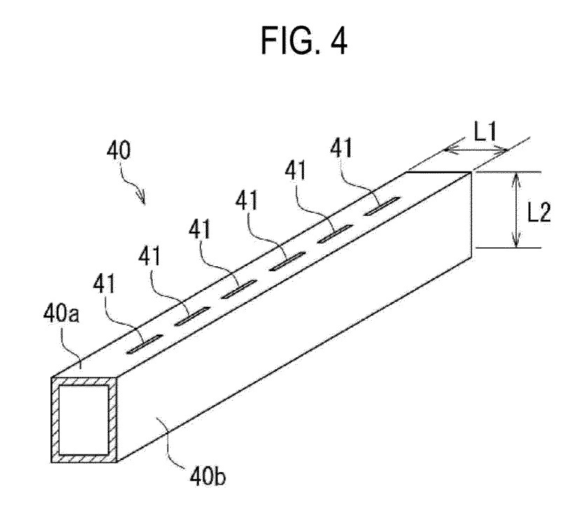

Next, referring to FIGS. 4 to 8, the arrangement and shape of the slot holes 41 of the antenna portion 40 will be described with specific examples. The arrangement and shape of the slot holes 41 are designed such that plasma is generated in the greater part of the opening of each of the slot holes 41 (on the entire surface of the opening in some embodiments). In order to make sure that plasma is generated in the greater part of the opening of each of the slot holes 41, the combination of the arrangement and shape of the slot holes 41 becomes important. From this viewpoint, certain types of arrangements and shapes of the slot holes 41 will be described below.

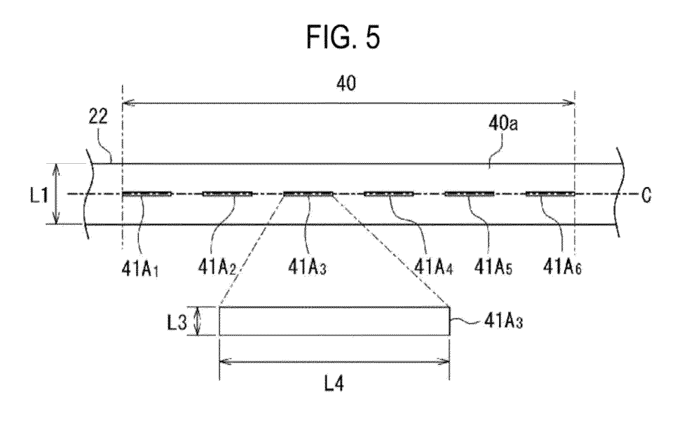

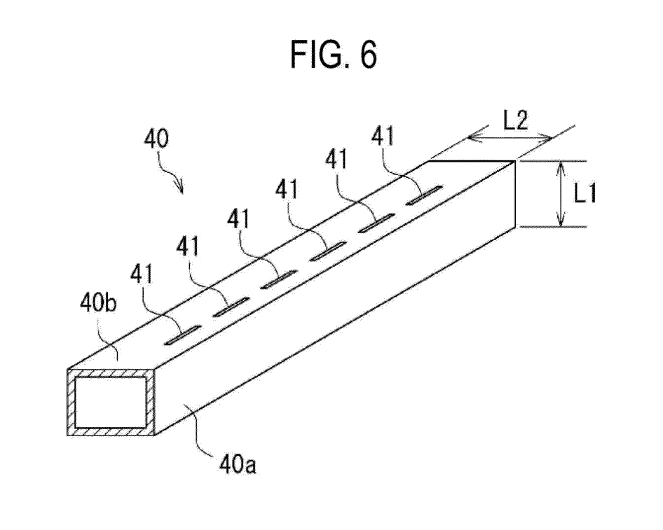

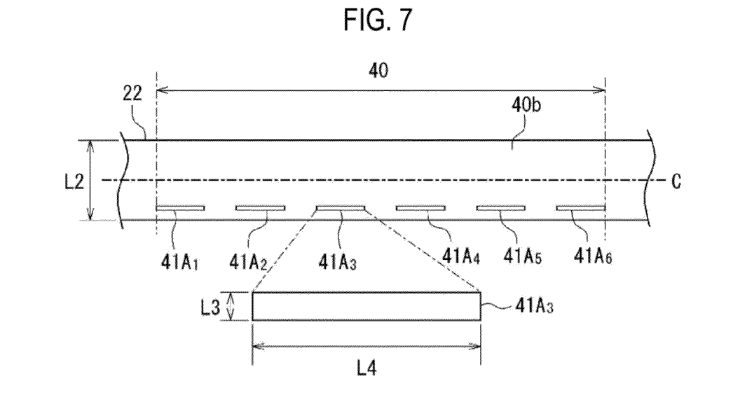

FIGS. 4, 5, 6 and 7 illustrate examples in which six rectangular slot holes 41 are formed in one wall 40a or 40b constituting the antenna portion 40. FIG. 4 shows a formation surface (a wall 40a) of the slot holes 41 of the antenna portion 40 of the rectangular waveguide 22 in an upwardly facing direction. FIG. 5 is a plan view of the wall 40a shown in FIG. 4. FIG. 6 shows another example of a formation surface (a wall 40b) of the slot holes 41 of the antenna portion 40 of the rectangular waveguide 22 in an upwardly facing direction. FIG. 7 is a plan view of the wall 40b shown in FIG. 6. In the plasma treatment device 100, the wall 40a or 40b arranged with the slot holes 41 is disposed opposite the substrate S.

As shown in FIGS. 4, 5, 6 and 7, the slot holes 41 may be formed at either one of the short-side-constituting wall 40a and the long-side-constituting wall 40b of the cross section of the antenna portion 40. In some embodiments, the slot holes 41 are formed at the short-side-constituting wall 40a. That is to say, if the length of the short side of the antenna portion 40 is L1 and that of the long side thereof is L2 (namely, L1<L2), as shown in FIGS. 4 and 5, the slot holes 41 may be arranged at the short-side-constituting wall 40a having the length L1. Electric waves as microwaves advance while being reflected between a pair of the short-side-constituting walls 40a of the rectangular waveguide 22 and reach an end surface of the rectangular waveguide 22. The electric waves, which are reflected by the end surface of the rectangular waveguide 22, move in the direction opposite to the advancing direction within the rectangular waveguide 22 and form standing waves. Magnetic waves orthogonal to the electric waves advance while being reflected between a pair of the long-side-constituting walls 40b of the rectangular waveguide 22. The magnetic waves, which are reflected by the end surface of the rectangular waveguide 22, move in the direction opposite to the advancing direction and form magnetic field standing waves. In this manner, the microwaves enter the inside of the antenna portion 40 as a portion of the rectangular waveguide 22 and form standing waves. If the slot holes 41 are formed in anti-node portions of the electric waves as the standing waves, it is possible to generate strong plasma. If the slot holes 41 are formed in the short-side-constituting wall 40a, a surface current flowing along the wall 40a flows in the direction orthogonal to the long-side-constituting wall 40b. For that reason, as long as the slot holes 41 are parallel to the longitudinal direction of the antenna portion 40, the surface current flows in the direction orthogonal to the slot holes 41, regardless of the position where the slot holes 41 are installed in the wall 40a. This makes it possible to obtain strong plasma. From the viewpoint of convenience in design, it is however preferred that the slot holes 41 are formed in the vicinity of the center of the short-side-constituting wall 40a (in the vicinity of a line (centerline) C extending in the longitudinal direction of the waveguide through the width direction center of the wall 40a.

Alternatively, as shown in FIGS. 6 and 7, the slot holes 41 may be formed at the long-side-constituting wall 40b. Even in this case, it is effective to generate strong plasma when the slot holes 41 are formed in the anti-node portions of the magnetic waves. According to electromagnetic field calculation for the rectangular waveguide 22, electric fields become stronger near a pair of the short-side-constituting walls 40a. Therefore, strong plasma can be obtained if the slot holes 41 are formed at positions nearer to the opposite walls 40a rather than the center of the wall 40b. For that reason, in FIGS. 6 and 7, the slot holes 41 are formed at positions deviated from a line (centerline) C extending in the longitudinal direction of the waveguide through the width direction center of the long-side-constituting wall 40b.

In FIGS. 5 and 7, six rectangular slot holes 41 formed at the wall 40a or 40b of the antenna portion 40 are designated by reference symbols 41A₁ to 41A₆. In FIGS. 5 and 7, the portion between outer ends of two slot holes 41A₁ and 41A₆ positioned most outward becomes the antenna portion 40. The arrangement interval of the slot holes 41A₁ to 41A₆ arranged along a line may be decided depending on the wavelength inside the waveguide. For the purpose of irradiating high-density plasma, the adjoining slot holes 41 may be positioned closer to each other and the interval between the adjoining slot holes 41 is smaller.

In addition, the length and width of the respective slot holes 41A₁ to 41A₆ are arbitrarily set. In some embodiments, the respective slot holes 41A₁ to 41A₆ have a narrow width and an elongated shape. If the length of the short side of the rectangular slot holes 41 (the width of the openings) is L3 and that of the long side thereof is LA, the length of the long side LA of the slot holes 41 may be set to be equal to or smaller than a half wavelength of the standing waves within the rectangular waveguide 22, with a view to reducing energy consumption and irradiating high-density plasma. In the tests conducted by the present inventors, it was found that, if the length of the short side L3 of the slot holes 41 is set to be as small as possible, it is possible to obtain a strong electric field strength and, consequently, to obtain high-density plasma. More specifically, in some embodiments, the length of the short side L3 is set equal to or smaller than 0.3 mm.

The respective slot holes 41 may be arranged such that the longitudinal direction of the slot holes 41 is coincident with, and parallel to, the longitudinal direction of the antenna portion 40 (namely, the longitudinal direction of the rectangular waveguide 22). If the longitudinal direction of the slot holes 41 is not parallel to the longitudinal direction of the antenna portion 40 and is formed to have an angle with respect to the longitudinal direction of the antenna portion 40, the slot holes 41 extend askew across the anti-node portions of the electric waves. It is therefore impossible to effectively use the anti-node portions of the strong electric waves. Thus, it becomes difficult to generate plasma over the entire opening of each of the slot holes 41.

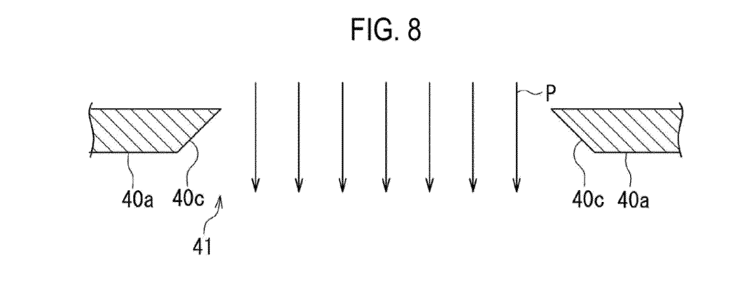

As shown in FIG. 8, in some embodiments, the edge surface 40c of the opening of each of the slot holes 41 is obliquely formed, such that the opening is enlarged from the inside toward the outside in the thickness direction of the wall 40a. By forming the edge surface 40c of each of the slot holes 41 into an oblique surface, it is possible to shorten the length of the short side L3 of the slot holes 41 at the inner wall surface side of the rectangular waveguide 22. This makes it possible to reduce discharge startup power, thereby keeping energy consumption low and generating high-density plasma. In addition, in FIG. 8, reference symbol P schematically shows plasma discharged from the slot holes 41.

When using a waveguide antenna, the standing waves of microwaves formed within the rectangular waveguide 22 are used when the microwaves are introduced into the rectangular waveguide 22. It is therefore desirable that the slot holes 41 are formed at the anti-node portions of the standing waves in order to generate strong plasma. For the sake of generating strong plasma at the slot holes 41, it is efficient to set the length of the slot holes 41 to become equal to or shorter than a half wavelength of the standing waves. Even if the slot holes 41 are formed at the node portions of the standing waves where electromagnetic fields remain weak, plasma is not generated at the slot holes 41. As set forth above, when using a waveguide antenna, plasma is not generated or weak plasma is generated at the node portions of the standing waves formed within the rectangular waveguide 22. Accordingly, it is desirable to form a plurality of slot rows within one rectangular waveguide 22 or to juxtapose a plurality of rectangular waveguides 22 each forming one slot row, thereby providing a structure in which the node portion having microwaves within one rectangular waveguide 22 is supplemented by the slot row of another rectangular waveguide 22.

A plurality of the slot holes 41 may be arranged either along a single line or in a plurality of rows. In case the slot holes 41 are formed at the short-side-constituting wall 40a of the rectangular waveguide 22, the surface current flowing along the surface of the wall 40a always flows in the direction orthogonal to a center axis of the short-side-constituting wall 40a. The center axis is along the longitudinal direction of the waveguide. Thus in some embodiments, the slot holes 41 are formed parallel to the center axis, which is along the longitudinal direction of the waveguide, of the short-side-constituting wall 40a. In the longitudinal direction of the waveguide, the slot holes 41 may be formed at positions of the anti-nodes of the standing waves. In the short side direction orthogonal to the longitudinal direction of the waveguide, the slot holes 41 may be essentially formed at any position. In view of the ease of machining and the ease of use, the slot holes 41 may be formed near the centerline C of the short-side-constituting wall 40a.

In case the slot holes 41 are formed at a surface of the long-side-constituting wall 40b of the rectangular waveguide 22, it is desirable that, for the purpose of obtaining strong plasma, the rectangular slot holes 41 are formed at the anti-node portions of the standing waves generated within the rectangular waveguide 22. In this case, the electromagnetic fields are maximized at the anti-node portions of the standing waves. The surface current flowing along the long-side-constituting wall 40b flows from the anti-node portions toward the short-side-constituting wall 40a. The surface current becomes larger toward the wall 40a of the rectangular waveguide 22. For that reason, if the rectangular slot holes 41 are formed on the wall surface of the long-side-constituting wall 40b near the short-side-constituting wall 40a of the rectangular waveguide 22, it becomes possible to generate strong plasma at the rectangular slot holes 41.

As set forth above, the plasma treatment device 100 is an atmospheric pressure plasma treatment device that does not require any vacuum vessel. Thus, there is no need to install a dielectric plate between the rectangular waveguide 22 and the substrate S. This makes it possible to prevent loss of the microwaves which may otherwise be caused by absorption of the microwaves at the dielectric plate. Since the plasma treatment device 100 is an atmospheric pressure plasma treatment device, it is not necessary to employ a pressure-resistant vacuum vessel, a seal mechanism or the like. This helps simplify the device configuration. For the purpose of increasing replacement efficiency of the treatment gases, etc., the plasma treatment device 100 may include exhaust equipment capable of generating a reduced pressure and a mechanism capable of discharging atmospheric pressure plasma into a closed space.

The plasma treatment device 100 is of a type in which the treatment gas supplied into the rectangular waveguide 22 is converted to plasma at the slot holes 41 by the microwaves and in which the plasma is discharged outside from the slot holes 41. Thus, it is not necessary to employ a dedicated gas introduction mechanism. This makes it possible to efficiently generate high-density plasma with a simple device configuration and to reduce the size of the device. That is to say, since the rectangular waveguide 22 plays the role of a shower head, there is no need to additionally install a gas introduction mechanism such as a shower head, a shower ring or the like. This makes it possible to simplify the device configuration. In the plasma treatment device 100, the microwaves are caused to act on the treatment gas within the rectangular waveguide 22. It is therefore possible to perform a treatment using high-density plasma while suppressing energy consumption to the utmost. For example, if the treatment gas includes a hydrogen gas, it is possible to perform a treatment with plasma which has a high hydrogen radical density. In the plasma treatment device 100, if the antenna portion 40 is formed into an elongated shape with a length of, e.g., about one meter, it becomes possible to perform a uniform plasma treatment with respect to the substrate S having a large area.

### [Method for Forming a Conductive Film]

Next, there will be described a method for forming a conductive film according to one embodiment of the present disclosure. The method for forming a conductive film according to one embodiment of the present disclosure includes a step of forming a precursor-containing film which contains metallic fine particles or metallic compounds and organic substances (a precursor-containing film forming step), and a step of irradiating plasma of a treatment gas including a hydrogen gas toward the precursor-containing film using an atmospheric pressure plasma treatment device, removing the organic substances and forming a conductive film from the metallic fine particles or the metallic compounds (a conductive film forming step). In the conductive film forming step, the treatment gas supplied into the rectangular waveguide 22 kept in an atmospheric pressure state is converted to plasma at the slot holes 41 by the microwaves. The plasma thus generated is irradiated from the slot holes 41 toward the precursor-containing film formed on the substrate S. At this time, the hydrogen radical density of the plasma at a position spaced apart 7 mm from the slot holes 41 is equal to or higher than 2×10¹⁴/cm³.

No particular limitation is imposed on the substrate S. For example, an inorganic substrate such as a glass substrate, a silicon substrate, a ceramic substrate or the like, or a substrate/film made of a synthetic resin such as a polyimide resin, polyethyleneterephthalate (PET) or the like, can be used as the substrate S depending on the purposes.

### <Precursor-Containing Film Forming Step>

The precursor-containing film contains metallic fine particles or metallic compounds as a precursor of a conductive film, and organic substances. In this regard, the kind of metals which constitute the metallic fine particles or the metallic compounds is not particularly limited as long as the metals have conductivity. It is possible to use metal species such as, e.g., gold (Au), silver (Ag), copper (Cu), cobalt (Co), nickel (Ni), palladium (Pd), platinum (Pt), tin (Sn), rhodium (Rh) or iridium (Ir). It may also be possible to use alloys of these metal species (e.g., a copper-nickel alloy and a platinum-cobalt alloy).

The average particle diameter of the metallic fine particles is not particularly limited as long as a conductive film can be formed by plasma irradiation. With a view to forming a high-quality conductive film which is low in specific resistance, the average particle diameter of the metallic fine particles may fall within a range of, e.g., 3 nm to 100 nm. Since the defect of a conductive film is reduced as the content of the metallic fine particles contained in the precursor-containing film grows larger, the content of the metallic fine particles may fall within a range of, e.g., 5 percent by mass to 80 percent by mass, with respect to the precursor-containing film.

The metallic compounds are not particularly limited as long as they are soluble in a solvent. Salts, complexes or the like of the aforementioned metals can be used as the metallic compounds. Examples of the metal salts include hydrochloride, sulfate, acetate, oxalate and citrate. Specific examples of the metallic compounds include Cu(CH₃COO)₂, CuSO₄, CuCO₃, CuBr₂, Cu(NH₄)₂Cl₄, CuI, Cu(NO₃)₂, Pd(CH₃COO)₂, Ni(CH₃COO)₂, NiSO₄, NiCO₃, NiCl₂, NiBr₂, Ni(NO₃)₂, NiC₂O₄, Ni(H₂PO₂)₂, Ni(CH₃COCH₂COCH₃)₂, PdSO₄, PdCO₃, CuCl₂, PdCl₂, PdBr₂, Pd(NO₃)₂, Cu(CH₃COCH₂COCH₃)₂, Pd(CH₃COCH₂COCH₃)₂, etc. It may also be possible to use complexes such as chloroauric acid tetrahydrate, silver acetate and the like. Two or more of the metallic compounds may be used in combination.

In order to form a conductive film which is low in specific resistance, the content of the metallic compounds may fall within a range of, e.g., 5 percent by mass to 80 percent by mass, on the basis of 100 percent by mass of the precursor-containing film.

Examples of the organic substances contained in the precursor-containing film include a binder component such as a resin or the like, a solvent, a capping agent, a dispersing agent and a viscosity modifier, all of which are contained in a coating liquid for use in the formation of the precursor-containing film. In the method for forming a conductive film according to the present embodiment, the organic substances are finally removed. Therefore, the kind and amount of the organic substances do not matter in particular.

No particular limitation is imposed on the method for forming the precursor-containing film. For example, the precursor-containing film can be formed by coating a coating liquid, which contains metallic fine particles or metallic compounds and organic substances, on the substrate S. The coating liquid can be coated by, e.g., a coating method using different kinds of coaters, a spraying method, a dipping method or the like. As an example, the coating liquid can be coated in a specified pattern by such methods as dispenser-used coating, inkjet printing, screen printing, gravure printing, nanoimprinting, etc.

After coating the coating liquid on the substrate S, it is desirable to dry the precursor-containing film which is the coated film. No particular limitation is imposed on the method for drying the precursor-containing film. It is desirable in some embodiments to perform, e.g., heat drying, under a temperature condition of from a room temperature to 300 degrees C. and for a period of from 1 minute to 30 minutes.

### <Conductive Film Forming Step>

In the conductive film forming step, an atmospheric pressure plasma treatment using a treatment gas including a hydrogen gas is performed with respect to the precursor-containing film through the aforementioned plasma treatment device 100. In the atmospheric pressure plasma treatment using the plasma treatment device 100, the plasma which is high in density of hydrogen radicals as active species can be directly irradiated to the precursor-containing film. Thus, the organic substances existing in the precursor-containing film are removed and a metallic conductive film is formed from the metallic fine particles or the metallic compounds. In case the precursor-containing film contains metallic fine particles, the metallic fine particles are flocculated and fused by the atmospheric pressure plasma treatment. Thus, a continuous conductive film is formed. If the precursor-containing film contains metallic compounds, metal ions derived from the metallic compounds are reduced by the atmospheric pressure plasma treatment, and metals are segregated. Thus, a continuous conductive film is formed. By using the treatment gas including a hydrogen gas, it is possible to form a high-quality conductive film which is low in specific resistance, without oxidizing the conductive film thus formed. By forming the precursor-containing film in a specified pattern as described above, it is possible to form a conductive film having a specified pattern.

In the conductive film forming step, the substrate S is initially carried into the treatment vessel 10 and mounted on the stage 50. That is to say, the substrate S is arranged such that the slot holes 41 of the antenna portion 40 can face the substrate S. Alternatively, the substrate S may be mounted on the stage 50 in such a state that the substrate S is supported on an arbitrary holder. Then, a treatment gas is introduced at a predetermined flow rate from the gas supply device 23 into the rectangular waveguide 22 through the gas introduction portion 22b and the branch pipe 22a. If the treatment gas is introduced into the rectangular waveguide 22, the internal pressure of the rectangular waveguide 22 becomes higher than the external atmospheric pressure.

Next, the power of the microwave generator 21 is turned on to generate microwaves. At this time, the microwaves may be generated in a pulse-like form. The microwaves are introduced into the rectangular waveguide 22 through a matching circuit which is not shown. By virtue of the microwaves thus introduced, electromagnetic fields are formed within the rectangular waveguide 22. The treatment gas supplied into the rectangular waveguide 22 is converted to plasma at the slot holes 41 of the antenna portion 40. This plasma is irradiated from an interior of the antenna portion 40 of the rectangular waveguide 22, in which the pressure is relatively high, toward the substrate S through the slot holes 41. In this way, a conductive film is formed by irradiating the plasma to the precursor-containing film formed on the substrate S, decomposing and removing the organic substances, and flocculating the metallic fine particles or reducing the metal ions derived from the metallic compounds. In this case, plasma is used in which the hydrogen radical density at a position spaced apart 7 mm from the slot holes 41 is equal to or higher than 2×10¹⁴/cm³.

### <Plasma Treatment Conditions>

Next, the plasma treatment conditions used in the conductive film forming step will be described.

### <Treatment Gas>

The treatment gas used in the plasma treatment contains a H₂ gas as a reducing gas. In some embodiments, the treatment gas contains a rare gas such as, e.g., Ar, Xe, Kr or the like, as a plasma-generating gas. Among them, Ar gas that can generate stable plasma may be used. As the treatment gas, a N₂ gas may be used in place of or in combination with the rare gas.

If an Ar gas and a H₂ gas are used as the treatment gas, the overall flow rate of the treatment gas is may be set to fall, e.g., within a range of from 10 slm to 50 slm, or in some embodiments within a range of from 20 slm to 40 slm, with a view to stably generate plasma and efficiently generate hydrogen radicals as active species in the plasma. With a view to efficiently generating hydrogen radicals as active species in the plasma, the percentage of H₂ gas in the treatment gas is in some embodiments set to fall, e.g., within a range of from 0.1 percent by volume to 4 percent by volume, and in other embodiments within a range of from 0.5 percent by volume to 4 percent by volume, and in alternate embodiments within a range of from 0.5 percent by volume to 2 percent by volume, an in other embodiments within a range of from 0.5 percent by volume to 1 percent by volume.

### <Microwaves>

In different embodiments, the frequency of the microwaves is set to fall, e.g., within a range of from 2.45 GHz to 100 GHz, or within a range of from 2.45 GHz to 10 GHz. With a view to efficiently generating hydrogen radicals, in different embodiments, the power of the microwaves is set to fall, e.g., within a range of from 500 W to 4000 W, or within a range of from 1000 W to 2000 W. In the plasma treatment, the microwaves may be generated in a pulse-like form. In this case, for example, a pulse-on time can be controlled to fall within a range of from 10μ0 ge of fr. In addition, a pulse-off time can be controlled to fall within a range of from 200μ00 e o00 0. The duty ratio can be controlled to fall within a range of from for example 5% to 70%, or within a range of from 10% to 50%.

### <Treatment Temperature>

The temperature of the substrate used in the plasma treatment may be a normal temperature (e.g., 20 degrees C.). However, with a view to increasing formation speed of the conductive film, the substrate is heated, for example, within a range of from room temperature to 300 degrees C., or within a range of from 100 degrees C. to 250 degrees C.

### <Treatment Pressure>

The pressure of the plasma treatment is a normal pressure. Thus, the method for forming a conductive film according to the present embodiment has an advantage in that it is not necessary to employ large-scale vacuum equipment.

### <Treatment Time>

The treatment time may be set such that a conductive film can be formed from metallic fine particles or metallic compounds. The treatment time can be properly set depending on the film thickness of the precursor-containing film, the amount of metallic fine particles or metallic compounds and the amount of organic substances. The treatment time in different embodiments is set to fall, e.g., within a range of from 30 seconds to 60 minutes, or within a range of from 1 minute to 30 minutes.

### <Hydrogen Radical Density>

The plasma treatment can be performed by plasma in which the hydrogen radical density at a position spaced apart 7 mm from the slot holes 41 is equal to or higher than 2×10¹⁴/cm³. By using the plasma in which the hydrogen radical density at a position spaced apart 7 mm from the slot holes 41 is equal to or higher than 2×10¹⁴/cm³, it becomes sufficiently possible, even at a normal temperature, to remove the organic substances in the precursor-containing film and to form the conductive film from the metallic fine particles or the metallic compounds. The hydrogen radical density can be measured by vacuum ultraviolet atomic absorption spectrometry (VUVABS) using a micro hollow cathode lamp.

In order to make sure that the plasma having a high hydrogen radical density is directly irradiated to the precursor-containing film, the plasma treatment is performed by setting the interval between the slot holes 41 and the precursor-containing film on the substrate S to fall within a range of from 1 mm to 12 mm. In this case, the hydrogen radical density in the plasma irradiated to the precursor-containing film formed on the substrate S is, e.g., equal to or higher than 0.7×10¹³/cm³. By using the plasma having a high hydrogen radical density in this manner, it is possible, in one plasma treatment, to form the conductive film from the metallic fine particles or the metallic compounds at an efficiency equal to or higher than the efficiency of an oxygen plasma treatment while avoiding oxidization of the conductive film.

As described above, the plasma treatment device 100 is of a type in which the treatment gas introduced into the rectangular waveguide 22 is converted to plasma at the slot holes 41 by virtue of the microwaves and discharged outside. Therefore, as compared with the conventional atmospheric pressure plasma treatment device, it is possible for the plasma treatment device 100 to generate high-density plasma. In this regard, the conventional atmospheric pressure plasma treatment device not shown refers to a type in which a dielectric plate is interposed between a microwave-guiding antenna and a stage (dielectric barrier type). In Table 1, there is shown a comparison of plasma parameters of the plasma treatment device 100 used in the present embodiment and the conventional plasma treatment device.

TABLE 1

| | Plasma | Conventional |
|---|---|---|
| | Treatment Device of | Type (Atmospheric |
| | Present Embodiment | Pressure Barrier Type) |
| Pressure | Atmospheric Pressure | Atmospheric Pressure |
| Electron Density | 1 × 10¹⁵ cm⁻³ | 1 × 10¹⁴ cm⁻³ |
| Hydrogen Radical | Discharge Portion | Dielectric Body Surface |
| Density | (Slot Holes): | 1 × 10¹⁴ cm⁻³ |
| (Treatment | 1 × 10¹⁵ cm⁻³ | |
| Gas: 1% H₂/Ar) | Position 7 mm away from | |
| | Discharge Portion: | |
| | 2 × 10¹⁴ cm⁻³ | |

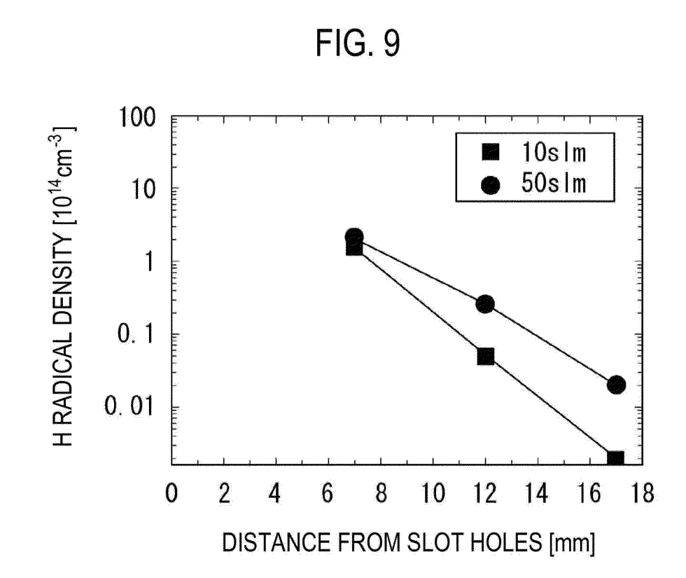

Next, test results forming the basis of the present disclosure will be described with reference to FIGS. 9 to 12. In the examples of the embodiment to be described below, there was used the antenna portion 40 which was 878 mm in total length and in which forty one rectangular slot holes 41 per row were linearly arranged along a centerline of the short-side-constituting wall of the rectangular waveguide 22. FIG. 9 is a graph illustrating the relationship between a distance from the slot holes 41 and the hydrogen radical density in plasma where atmospheric pressure plasma is generated under the same conditions, except that the distance from the slot holes 41 to the point measured by vacuum ultraviolet atomic absorption spectrometry (VUVABS) is changed to between 7 mm and 17 mm (7 mm, 12 mm and 17 mm) A mixed gas of an Ar gas and a H₂ gas was used as the treatment gas. The total flow rate was set to 10 slm or 50 slm. In any total flow rate, the hydrogen concentration was set to 1 percent by volume. The pressure of the atmosphere was set to 1 atm. The frequency of the microwaves was set to 10 GHz. The power was set to 1.5 kW. The microwaves were generated in a pulse-like form at a pulse frequency of 4 kHz, a pulse-on time of 40 μs and a duty ratio of 16%.

It can be noted from FIG. 9 that the hydrogen radical density in the plasma decreases as the distance from the slot holes 41 grows longer. Further, in any flow rate of the treatment gas, the hydrogen radical density at a position spaced apart 7 mm from the slot holes 41 is substantially equal to 2×10¹⁴/cm³. Accordingly, under the aforementioned conditions, if the precursor-containing film of the substrate S is disposed at the distance of 7 mm or less from the slot holes 41, it becomes possible to perform a treatment using the atmospheric pressure plasma having a high hydrogen radical density of 2×10¹⁴/cm³ or higher. The use of the plasma having a high hydrogen radical density of 2×10¹⁴/cm³ or higher makes it possible to decompose and remove the organic substances in the precursor-containing film substantially at a normal temperature. Thus, it becomes possible to form a conductive film from metallic fine particles or metallic compounds. If the substrate S (the precursor-containing film) is heated to, e.g., 250 degrees C., even if the hydrogen radical density is about 0.7×10¹³/cm³, it is possible to decompose and remove the organic substances in the precursor-containing film. Therefore, it becomes possible to form a conductive film from metallic fine particles or metallic compounds. In FIG. 9, the distance from the slot holes 41, at which the hydrogen radical density becomes 0.7×10¹³/cm³ under the aforementioned conditions, is about 12 mm. Accordingly, if the combined use of a heat treatment is considered, the distance from the slot holes 41 to the surface of the substrate S may be set to 12 mm or less and may be set to, e.g., within a range of from 1 mm to 12 mm, or within a range of from 1 mm to 7 mm because there is no need to perform a heat treatment. The lower limit value, 1 mm, in the aforementioned range is an interval to avoid contact of the substrate S with the slot holes 41. In view of efficiency of the plasma treatment, the lower limit value is set closer to 0 mm.

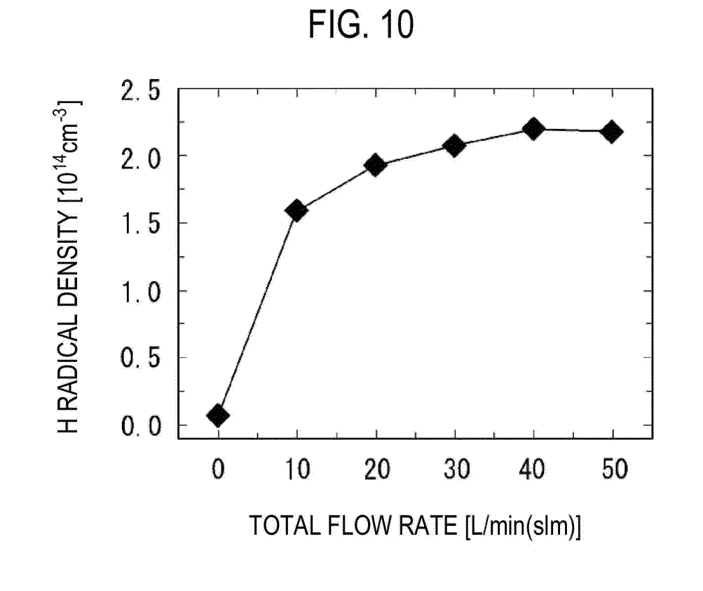

FIG. 10 is a graph illustrating the relationship between the total flow rate of the treatment gas and the hydrogen radical density in the plasma where atmospheric pressure plasma is generated under the same conditions, except that the total flow rate of the treatment gas is changed. A mixed gas of an Ar gas and a H₂ gas was used as the treatment gas. The total flow rate was changed to between 0 to 50 slm (0, 10, 20, 30, 40 and 50 slm). In any total flow rate, the hydrogen concentration was set to 1 percent by volume. The distance from the slot holes 41 to the point measured by vacuum ultraviolet atomic absorption spectrometry (VUVABS) was set to 7 mm. The pressure of the atmosphere was set to 1 atm. The frequency of the microwaves was set to 10 GHz. The power was set to 1.5 kW. The microwaves were generated in a pulse-like form at a pulse frequency of 4 kHz, a pulse-on time of 40 μs and a duty ratio of 16%.

It can be noted from FIG. 10 that the hydrogen radical density sharply increases when the total flow rate of the treatment gas is within a range of from 0 to 10 slm. Further, the hydrogen radical density gently increases when the total flow rate of the treatment gas is within a range of from 10 to 40 slm. The hydrogen radical density reaches 2×10¹⁴/cm³ or higher when the total flow rate of the treatment gas is 20 slm. The hydrogen radical density remains substantially flat until the total flow rate reaches 50 slm. Accordingly, in view of efficiently generating hydrogen radicals as active species in the plasma, it is considered that the total flow rate of the treatment gas should be set to fall within a range of from 10 slm to 50 slm, or within a range of from 20 slm to 40 slm.

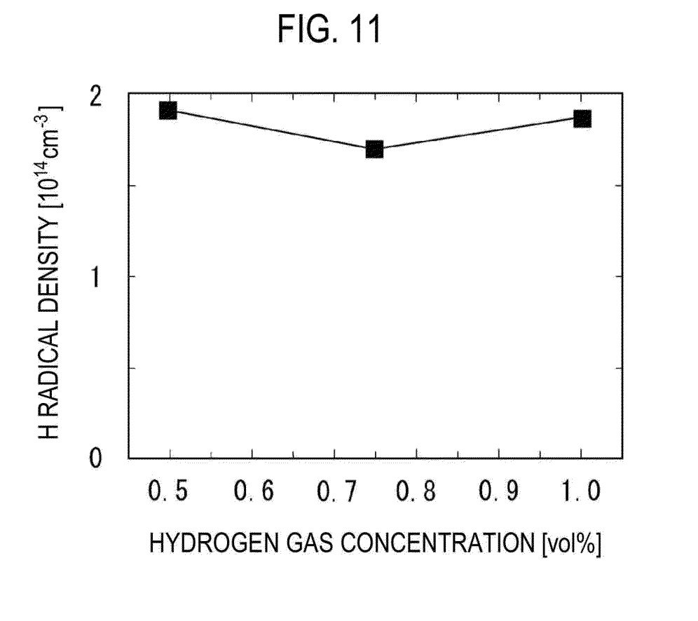

FIG. 11 is a graph illustrating the relationship between a H₂ gas concentration in the treatment gas and the hydrogen radical density in plasma where atmospheric pressure plasma is generated under the same conditions, except that the H₂ gas concentration (flow rate percentage) in the treatment gas is changed. A mixed gas of an Ar gas and a H₂ gas was used as the treatment gas. The total flow rate was set equal to 10 slm. The volumetric percentage of the H₂ gas was changed to between 0.5 to 1.0% (0.5%, 0.75% and 1.0%). The distance from the slot holes 41 to the point measured by vacuum ultraviolet atomic absorption spectrometry (VUVABS) was set to 7 mm. The pressure of the atmosphere was set to 1 atm. The frequency of the microwaves was set to 10 GHz. The power was set to 1.5 kW. The microwaves were generated in a pulse-like form at a pulse frequency of 4 kHz, a pulse-on time of 40 μs and a duty ratio of 16%.

It can be seen from FIG. 11 that, even if the H₂ gas concentration in the treatment gas is changed within the predetermined range, the hydrogen radical density in the atmospheric pressure plasma is not significantly changed but is kept in a substantially flat state. Accordingly, the volumetric percentage of the H₂ gas in the treatment gas is not limited to the range of from 0.5% to 1.0% but may be set to fall, e.g., within a range of from 0.1% to 4%. However, with a view to suppressing the amount of the H₂ gas usage while obtaining a sufficient reducing action, it is considered that the volumetric percentage of the H₂ gas in the treatment gas should be set, for example, to fall within a range of from 0.5 percent by volume to 4 percent by volume, within a range of from 0.5 percent by volume to 2 percent by volume, or within a range of from 0.5 percent by volume to 1 percent by volume.

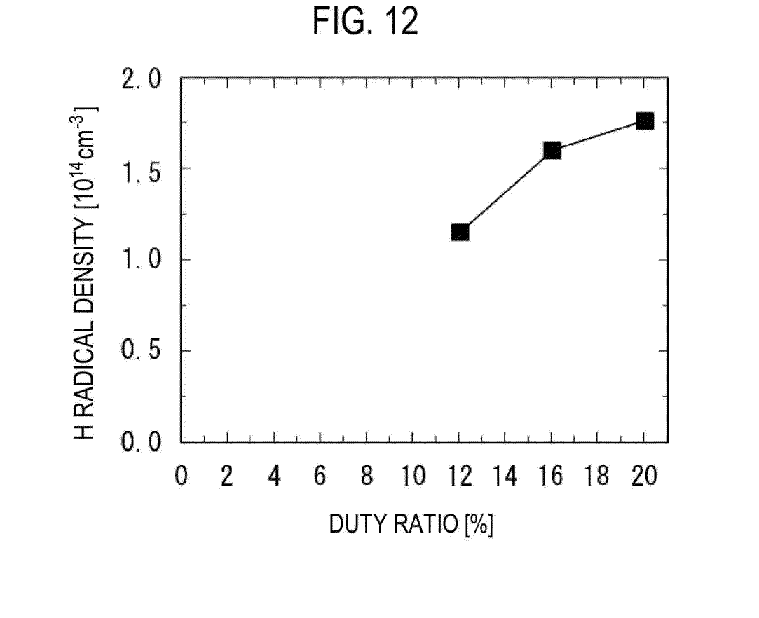

FIG. 12 is a graph illustrating the relationship between the duty ratio of a microwave pulse and the hydrogen radical density in the plasma where atmospheric pressure plasma is generated under the same conditions, except that the duty ratio of the microwave pulse is changed. The microwaves were generated in a pulse-like form at a pulse frequency of 4 kHz, a pulse-on time of 30 to 50 is (30 μs, 40 μs and 50 μs) and a duty ratio of 12 to 20% (12%, 16% and 20%). A mixed gas of an Ar gas and a H₂ gas was used as the treatment gas. The total flow rate was set to 10 slm. The hydrogen concentration in the treatment gas was set to 1 percent by volume. The distance from the slot holes 41 to the point measured by vacuum ultraviolet atomic absorption spectrometry (VUVABS) was set to 7 mm. The pressure of the atmosphere was set to 1 atm. The frequency of the microwaves was set to 10 GHz. The power was set to 1.5 kW.

It can be noted from FIG. 12 that the duty ratio and the hydrogen radical density in the plasma are directly proportional to each other. If the duty ratio becomes higher, the hydrogen radical density increases. As mentioned above, the duty ratio is set, e.g., equal to or higher than 5%. In order to efficiently generate hydrogen radicals as active species in the plasma and to increase efficiency of an atmospheric pressure plasma treatment, the duty ratio may be set to be equal to or higher than 10%. In order to avoid overheating of the antenna portion 40, it is considered that the upper limit of the duty ratio is set to 70% as mentioned above, or set to 50%.

### [Heat Treatment]

In the method for forming a conductive film according to the present embodiment, a conductive film having a low specific resistance and a superior conductivity can be formed, by subjecting the precursor-containing film to an atmospheric pressure plasma treatment through the use of the plasma treatment device 100. Alternatively, prior to performing the atmospheric pressure plasma treatment, the precursor-containing film may be subjected to a heat treatment for a period from 1 minute to 30 minutes, at a temperature range of, e.g., from a room temperature to 300 degrees C., or from 100 degrees C. to 250 degrees C. If, as a part of the conductive film forming step, the heat treatment is performed in combination with the atmospheric pressure plasma treatment, it is possible to increase the formation speed of the conductive film and thus to enhance throughput. By combining the heat treatment with the atmospheric pressure plasma treatment, it is possible to significantly reduce the heat treatment temperature, as compared with a case where a conductive film is formed from metallic fine particles or metallic compounds by performing only heat treatment. If the atmospheric pressure plasma treatment is performed subsequent to the heat treatment, it is possible to implement the atmospheric pressure plasma treatment while maintaining a heating temperature of the precursor-containing film used in the heat treatment.

The method for forming a conductive film according to the present embodiment can be used in forming electrodes or wiring lines during the manufacture of, e.g., a rigid printed board, a flexible printed board, a FPD (Flat Panel Display), a solar cell, an organic EL element or the like.

Next, the examples of the present embodiment were described, which were implemented using the plasma treatment device configured as shown in FIG. 1. However, the present disclosure is not limited to the examples illustrated herein below. In the following examples of the present embodiment, there was used the antenna portion 40 which was 878 mm in total length and in which forty one rectangular slot holes 41 per row were linearly arranged along a centerline of the short-side-constituting wall of the rectangular waveguide 22. Plasma was generated such that the hydrogen radical density at a position spaced apart 7 mm from the slot holes 41 was equal to or higher than 2×10¹⁴/cm³. The interval between the slot holes 41 and the substrate was set to 6 mm.

### Example 1

### Formation of a Conductive Film from Silver Nano Particles

An ink (JAGT-05, a product of DIC Corporation) obtained by dispersing silver nano particles (having a maximum diameter of 20 nm) and a capping agent in a solvent (water or ethanol) was used as a conductive ink. This ink was coated on a substrate and was subjected to a heat treatment in the atmospheric air at 180 degrees C. for 30 minutes (under the maker-recommended conditions), thereby obtaining a conductive silver thin film having a specific resistance value of 30 μΩ·cm or less.

The ink was coated on a silicon wafer having a thermal oxide film (of 100 nm in thickness) by the spin coat method. The dripping amount of the ink was 0.5 mL and the spin coat conditions were 2000 rpm and 10 seconds. Thereafter, a drying treatment for the coated film was performed at 100 degrees C. for 5 minutes through the use of a hot plate. By virtue of this drying treatment, the solvent in the coated film containing silver nano particles was evaporated to dry the coated film. Due to this drying treatment, the coated film is stabilized and can be preserved for a long period of time.

Next, the coated film thus dried was heated and subjected to a plasma treatment for 5 minutes through the use of an atmospheric pressure plasma treatment device at the same time. A mixed gas of an Ar gas and a H₂ gas was used as a treatment gas. The total flow rate of the treatment gas was set to 20 slm. The flow rate percentage of the H₂ gas was set to 1 percent by volume. The pressure of the atmosphere was set to 1 atm. The frequency of microwaves was set to 10 GHz and the power thereof was set to 1.5 kW. The microwaves were generated in a pulse-like form at a pulse frequency of 4 kHz, a pulse-on time of 40 μs and a duty ratio of 16%. The heating was performed using a heater installed below the silicon wafer as a sample. The heater temperature was set such that the silicon wafer temperature becomes about 180 degrees C.

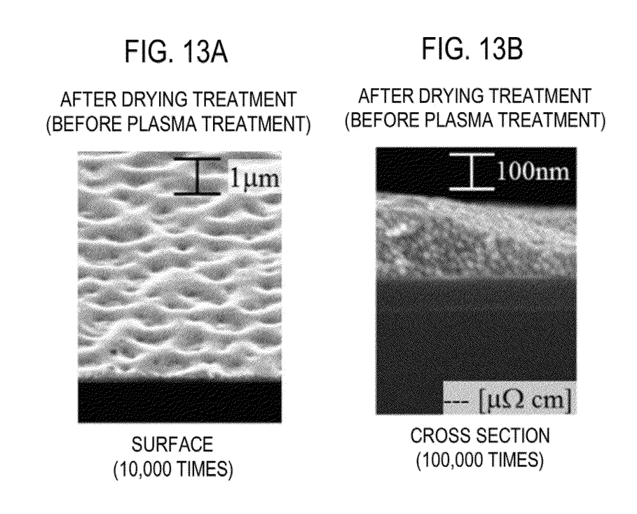

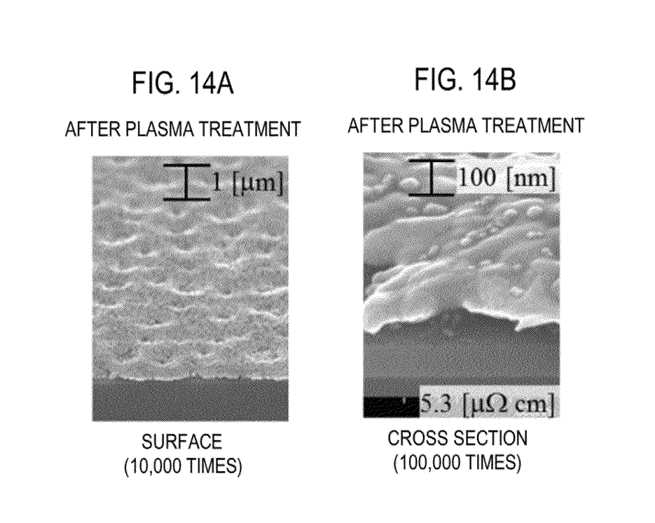

FIGS. 13A and 13B show SEM images of the coated film containing silver nano particles prior to performing the atmospheric pressure plasma treatment (after performing the drying treatment). FIGS. 14A and 14B show SEM images of the conductive film after performing the atmospheric pressure plasma treatment. It can be confirmed from FIGS. 13A, 13B, 14A and 14B that the silver nano particles individually dispersed and kept in an initial state prior to the atmospheric pressure plasma treatment are mutually flocculated and converted to a uniform metal film by the atmospheric pressure plasma treatment. The specific resistance value of the coated film after the drying treatment was immeasurable (due to insulation property). However, the specific resistance value after the atmospheric pressure plasma treatment was 5.3 μΩ·cm, which means that the conductive film has superior conductivity. Moreover, the specific resistance value after the atmospheric pressure plasma treatment was about ⅙ of the specific resistance value (30 μΩ·cm or less) after the heat treatment is performed under the maker-recommended conditions. This means that the conductive film has superior conductivity.

The above results reveal that, if the atmospheric pressure plasma treatment is performed, as compared with a case where only the heat treatment is performed, it is possible to form a conductive film having a low resistance within a short period of time.

### Example 2

### Formation of a Conductive Film from a Copper Complex

An ink (ADEKAOLCERA CM-11, a product of ADEKA Corporation) obtained by dissolving a copper complex and a stabilizer in a solvent (ethanol) was used as a conductive ink. This ink was coated on a substrate and was subjected to a heat treatment in an argon atmosphere at 250 degrees C. for 40 minutes (under the maker-recommended conditions). Thus, a conductive copper thin film having a specific resistance value of 60 μΩ·cm or less is obtained.

The ink was coated on a silicon wafer having a thermal oxide film (of 100 nm in thickness) through the spin coat method. The dripping amount of the ink was 0.5 mL and the spin coat conditions were 2500 rpm and 15 seconds. Thereafter, a drying treatment for the coated film containing a copper complex was performed at 140 degrees C. for 1 minute through the use of a hot plate. By virtue of this drying treatment, the solvent in the coated film was evaporated, thereby drying the coated film.

Next, the coated film thus dried was heated and subjected to a plasma treatment through the use of an atmospheric pressure plasma treatment device at the same time. First, the silicon wafer was heated at about 250 degrees C. for 1 minute using a heater. The heating was performed using a heater installed below the silicon wafer as a sample. Then, an atmospheric pressure plasma treatment was performed for 10 minutes while maintaining the heating temperature of the silicon wafer at 250 degrees C. A mixed gas of an Ar gas and a H₂ gas was used as a treatment gas. The total flow rate of the treatment gas was set to 20 slm. The flow rate percentage of the H₂ gas was set to 1 percent by volume. The pressure of the atmosphere was set to 1 atm. The frequency of microwaves was set to 10 GHz and the power thereof was set to 1.5 kW. The microwaves were generated in a pulse-like form at a pulse frequency of 4 kHz, a pulse-on time of 40 μs and a duty ratio of 16%.

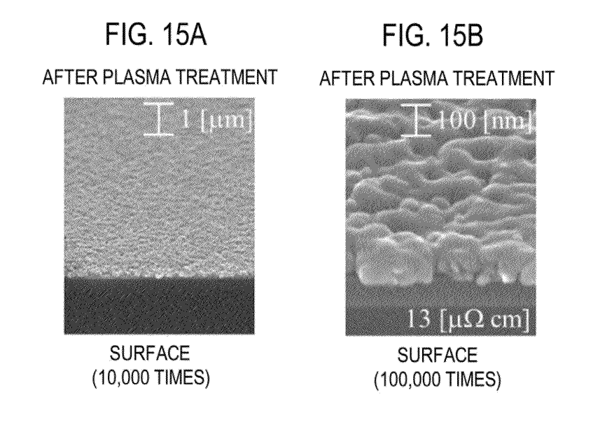

FIGS. 15A and 15B show SEM images of a conductive film obtained after performing the atmospheric pressure plasma treatment. It can be confirmed from FIGS. 15A and 15B that, while some pores are observed, the coated film was mostly converted to a continuous metal film through the atmospheric pressure plasma treatment. The specific resistance value of the coated film before the atmospheric pressure plasma treatment (after the drying treatment) was immeasurable (due to insulation property). However, the specific resistance value after the atmospheric pressure plasma treatment was 13 μΩ·cm, which means that the conductive film has superior conductivity. From these results, it is considered that the metallic compounds contained in the coated film are reduced by the atmospheric pressure plasma treatment, whereby metal copper is generated. Moreover, the specific resistance value after the atmospheric pressure plasma treatment was about ⅕ of the specific resistance value (60 μΩ·cm or less) when the heat treatment is performed under the maker-recommended conditions. This means that the conductive film has superior conductivity.

The dried coated film (containing a copper complex) was subjected to a heat treatment at 200 degrees C. for 10 minutes. Thereafter, while maintaining the same temperature, the coated film was subjected to an atmospheric pressure plasma treatment for 10 minutes. The plasma treatment conditions are the same as above except the heating temperature. As a result, it was possible to form a copper thin film having a conductivity of 28 μΩ·cm in specific resistance.

The aforementioned results reveal that, if the ink containing metallic compounds is heated and subjected to the atmospheric pressure plasma treatment at the same time, it is possible to form a conductive film having a low resistance at a low temperature and within a short period of time, as compared with a case where only the heat treatment is performed.

As described above, in the method for forming a conductive film according to the present embodiment, the rectangular waveguide 22 superior in microwave transmission efficiency is used. The rectangular waveguide 22 has the slot holes 41 formed at the wall thereof. The plasma treatment device 100 of an atmospheric pressure plasma type is used, which directly supplies a treatment gas into the rectangular waveguide 22. By treating metallic fine particles or metallic compounds with the plasma having a high hydrogen radical density, it is possible to form a high-quality conductive film from the metallic fine particles or the metallic compounds within a short period of time.

While one embodiment of the present disclosure has been described above in detail for the sake of illustration, the present disclosure is not limited to the aforementioned embodiment but may be modified in many different forms.

This international application claims the priority of Japanese Patent Application No. 2012-041556, filed on Feb. 28, 2012, the entire content of which is incorporated herein by reference.

What is claimed is:

1. A method for forming a conductive film on a substrate, comprising:
forming a precursor-containing film, which contains metallic fine particles or metallic compounds and organic substances, on the substrate; and
irradiating plasma of a treatment gas including a hydrogen gas on the precursor-containing film by an atmospheric pressure plasma treatment device thereby removing the organic substances and forming a conductive film from the metallic fine particles or the metallic compounds,
wherein the atmospheric pressure plasma treatment device includes a microwave generator configured to generate microwaves, a hollow waveguide connected to the microwave generator and elongated in a transmission direction of the microwaves, the waveguide having a rectangular cross section in a direction orthogonal to the transmission direction, a gas supply device connected to the waveguide and configured to supply the treatment gas into the waveguide, and an antenna portion which constitutes a portion of the waveguide and has one or more rectangular slot holes, the antenna portion configured to discharge plasma generated by the microwaves to the outside,
wherein the one or more rectangular slot holes are formed at a short-side-constituting wall of a cross section of the antenna portion such that the transmission direction of the microwaves coincides with a longitudinal direction of the slot holes, and
wherein irradiating plasma of a treatment gas comprises supplying the treatment gas into the waveguide kept in an atmospheric pressure state being converted to plasma at the slot holes by the microwaves, the plasma thus generated being irradiated from the slot holes toward the precursor-containing film formed on the substrate, and a hydrogen radical density of the plasma at a position spaced apart 7 mm from the slot holes being equal to or higher than 2×10¹⁴/cm³.

2. The method of claim 1, wherein the irradiation of the plasma is performed by setting an interval between the slot holes and the precursor-containing film to fall within a range of from 1 mm to 12 mm.

3. The method of claim 1, wherein the plasma is generated by using a mixed gas of a hydrogen gas and an argon gas as the treatment gas and setting a total flow rate of the treatment gas including the hydrogen gas at a percentage of 0.5 percent by volume to 4 percent by volume to fall within a range of from 10 slm (a standard state L/min) to 50 slm (a standard state L/min).

4. The method of claim 1, wherein the plasma treatment device further includes a pulse generator and generates the plasma by generating the microwaves in a pulse-like form at a duty ratio of 5% or more.

5. The method of claim 1, wherein prior to irradiating the plasma, the precursor-containing film is heated to a temperature of from room temperature to 300 degrees C. and the plasma is irradiated while maintaining the temperature.
